(19) United States
(12) Patent Application Publication
(10) Pub. No.: US 2008/0203553 A1
(43) Pub. Date: Aug. 28, 2008

(54) Stackable bare-die package

(75) Inventors: Hung-Hsin Hsu, Hsinchu (TW); Hwe-Zhong Chen, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/709,893

(22) Filed: Feb. 23, 2007

(51) Int. Cl. H01L 23/02

(52) U.S. Cl. 257/686; 257/E23.085; 257/E23.18

(57) ABSTRACT

A stackable bare-die package primarily comprises a substrate, a chip, a plurality of bonding wires and an encapsulant. The substrate has a slot where a step is formed inside the slot where a plurality of inner fingers are disposed on the step. A plurality of outer pads are disposed on the bottom surface and a plurality of transfer pads on the top surface. The chip is disposed on the top surface and is electrically connected to the inner fingers by a plurality of bonding wires passing through the slot. An encapsulant is formed inside the slot to encapsulate the bonding wires. There is a height difference between the step and the bottom surface so that the loop height of the bonding wires will not exceed the bottom surface. Therefore, when stacking the stackable bare-die packages, the exposed back surface of the chip will not be touched nor stressed to avoid die crack issues.

### FIELD OF THE INVENTION

The present invention relates to an IC package, especially, to a stackable bare-die package for high density POP (Package-On-Package) application.

### BACKGROUND OF THE INVENTION

In order to increase the memory capacity within the same package footprint, stackable chip packages have gradually replaced the single-die packages. A plurality of stackable chip packages are stacked together, which have become the major trend in IC packaging technologies. However, in order to increase heat dissipation capability and to lower the die thicknesses and weights, the stackable chip packages will expose the backsides of the chips which are easily damaged such as chipping or cracks during packaging processes.

As shown in FIG. 1, a conventional a stackable bare-die package 100 primarily comprises a substrate 110, a chip 120, a plurality of bonding wires 130 and an encapsulant 140 where the substrate 110 has a top surface 111, a bottom surface 112 and a slot 113. A plurality of outer pads 114 and a plurality of inner fingers 116 are disposed on the bottom surface 112 where the inner fingers 116 are disposed on both sides of the slot 113. A plurality of transfer pads 115 are disposed on the top surface 112. The chip 120 has an active surface 121 and an exposed back surface 123 where a plurality of bonding pads 122 are disposed on the active surface 121 and are aligned in the slot 113. The active surface 121 of the chip 120 is attached to the top surface 111 of the substrate 110 by a die-attaching layer 160. The bonding pads 122 are electrically connected to the inner fingers 116 by the bonding wires 130 passing through the slot 113. The encapsulant 140 is formed in the slot 113 to encapsulate the bonding wires 130 with the back surface 123 exposed. The encapsulant 140 has an extrusion 141 extruded from the bottom surface 112 of the substrate 110 in order to fully encapsulate the bonding wires 130. As shown in FIG. 1, a plurality of external terminals 150 are disposed on the outer pads 114 for electrically connecting to a printed circuit board 10 or for stacking on the transfer pads 115 of another stackable bare-die package 100. However, when stacking the stackable bare-die packages 100, the extrusion 141 of the encapsulant 140 will touch and stress the exposed back surface 123 of the chip 120 of another MCP 100 under it causing die cracks of the chip 120 or breaks of the external terminals 150, i.e., the overall yield will suffer.

### SUMMARY OF THE INVENTION

The main purpose of the present invention is to provide a stackable bare-die package with a step formed in the slot to eliminate the height of the extrusion of the encapsulant and to avoid a package encapsulant of an upper package to touch and stress on the exposed back surface of chip of a lower package to eliminate die cracks or/and terminal breaks during POP (Package-On-Package) stacking processes.

According to the present invention, a stackable bare-die package primarily comprises a substrate, a chip, a plurality of bonding wires and an encapsulant where the substrate has a top surface, a bottom surface and a slot. A step is formed in the slot. The substrate further has a plurality of outer pads disposed on the bottom surface, a plurality of transfer pads disposed on the top surface and a plurality of inner fingers disposed on the step. The chip is disposed on the top surface of the substrate with a plurality of bonding pads aligned in the slot where the bonding pads are electrically connected to the inner fingers by a plurality of bonding wires. The encapsulant is formed in the slot to completely encapsulate the bonding wires. The chip has an exposed back surface. There is a height difference between the step and the bottom surface of the substrate in a manner that the loop heights of the bonding wires don't exceed the bottom surface. Preferably, the encapsulant has an exposed surface coplanar to the bottom surface.

### DESCRIPTION OF THE DRAWINGS

FIG. 1 shows a cross-sectional view of a conventional stackable bare-die package.

FIG. 2 shows a cross-sectional view of a stackable bare-die package according to the first embodiment of the present invention.

FIG. 3 shows a three-dimensional view of the substrate of the stackable bare-die package during wire-bonding processes according to the first embodiment of the present invention.

FIG. 4 shows a cross-sectional view of the stackable bare-die package during POP stacking processes according to the first embodiment of the present invention.

FIG. 5 shows a cross-sectional view of another stackable bare-die package according to the second embodiment of the present invention.

FIG. 6 shows a three-dimensional view of the substrate of the stackable bare-die package during wire-bonding processes according to the second embodiment of the present invention.

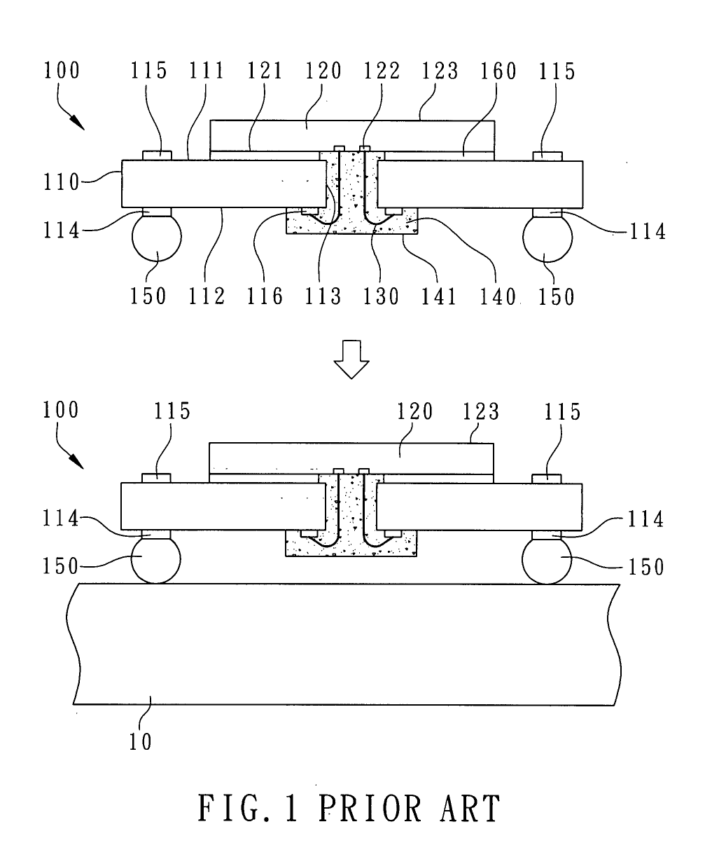

### DETAIL DESCRIPTION OF THE INVENTION

Please refer to the attached drawings, the present invention will be described by means of embodiment(s) below.

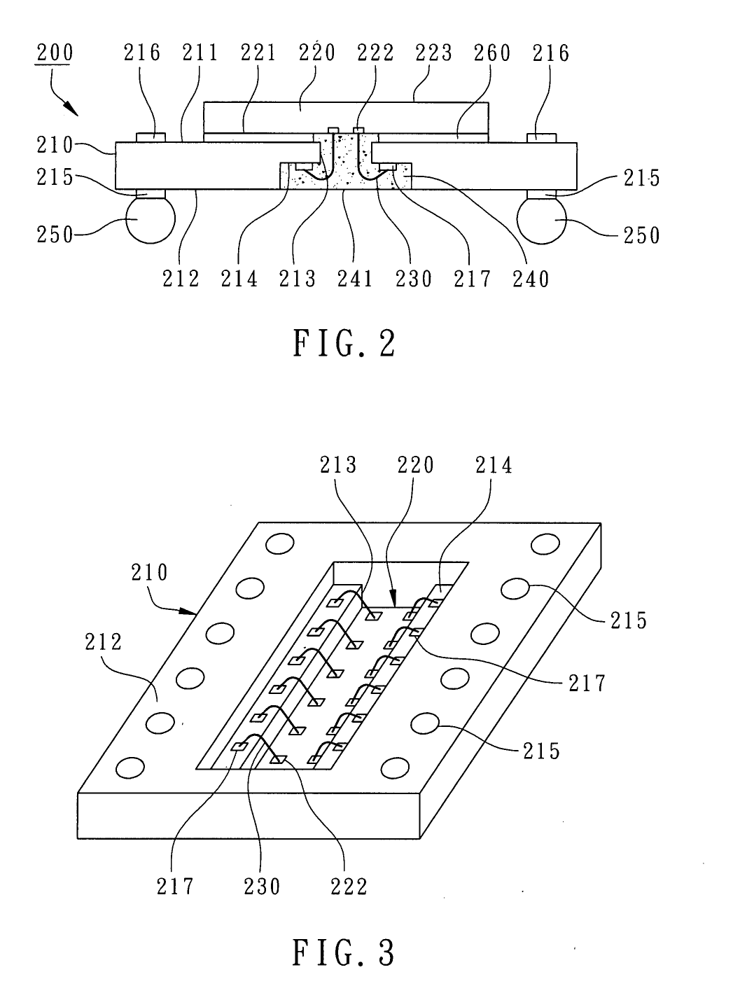

According to the first embodiment of the present invention, as shown in FIG. 2, a stackable bare-die package 200 primarily comprises a substrate 210, a chip 220, a plurality of bonding wires 230 and an encapsulant 240 where the substrate 210 has a top surface 211, a bottom surface 212 and a slot 213. In the present embodiment, the slot 213 penetrates through the top surface 212 and the bottom surface 213 for passing through the bonding wires 230. The substrate 210 at least has a layer of traces and PTH's, not shown in the figure, which is electrically connected the top surface 211 to the bottom surface 212. As shown in FIG. 3, a step 214 is formed inside the slot 213 where the opening of the step 214 is toward the bottom surface 212. The step 214 is a portion of the substrate 210 thinner than the thickness from the top surface 211 to the bottom surface 212 of the substrate. The substrate 210 further has a plurality of outer pads 215, a plurality of transfer pads 216 and a plurality of inner fingers 217 where the outer pads 215 are disposed on the bottom surface 212, the transfer pads 216 on the top surface 211, and the inner fingers 217 on the step 214 inside the slot 213. The inner fingers 217 are electrically connected to at least parts of the outer pads 215 through the patterned traces of the substrate 210 for external electrical connections. The transfer pads 216 are electrically connected to at least parts of the outer pads 215 for stacking electrical connections.

As shown in FIG. 2, the chip 220 has an active surface 211 and a corresponding exposed back surface 223 where a plurality of bonding pads 222 are disposed on the active surface 221 as electrodes for the chip. The active surface 221 of the chip 220 is attached to the top surface 211 of the substrate 210 by a die-attaching layer 260 with the bonding pads 222 aligned in the slot 213, as shown in FIG. 3. In the present embodiment, the chip 220 can be a memory chip such as flash memory or DRAM chip. After die attachment, the bonding pads 222 of the chip 220 are electrically connected to the inner fingers 217 of the substrate by the bonding wires 230 passing through the slot 213.

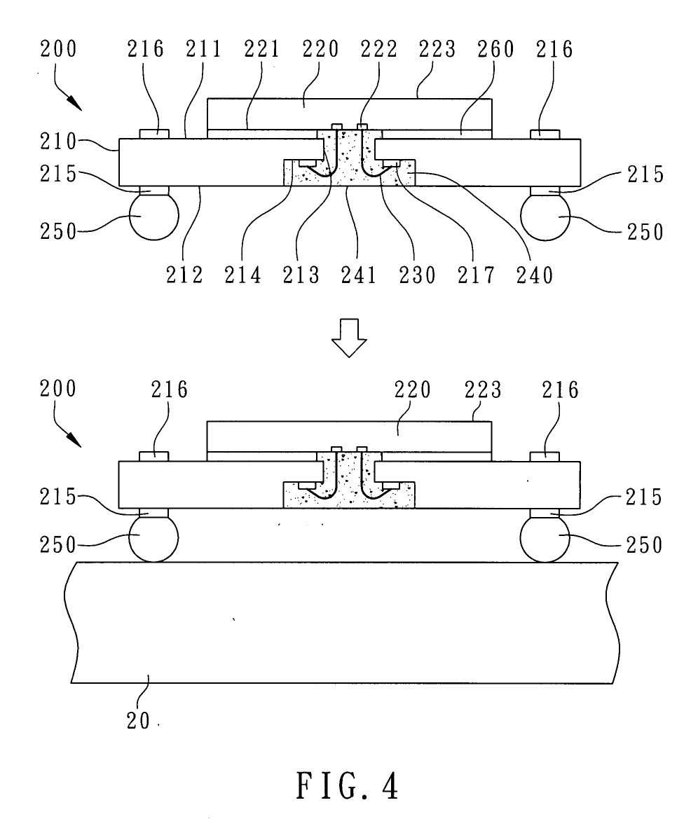

An encapsulant 240 is formed inside the slot 213 to completely encapsulate the bonding wires 230 where the encapsulant 240 is formed by transfer molding or dispensing. As shown again in FIG. 2 and FIG. 3, there is a height difference between the step 214 and the bottom surface 212 in a manner that the loop heights of the bonding wires 230 don't exceed the bottom surface 212. Accordingly, the encapsulant 240 fully encapsulating the bonding wires 230 has a reduced height without extruded from the bottom surface 212. In the present embodiment, the height difference between the step 214 and the bottom surface 212 can not be smaller than 70 μm. To be more specific, the top surface 211 of the substrate 210 is not encapsulated by the encapsulant 240 to expose the exposed back surface 223 of the chip and the transfer pads 216 for electrical connections to another stackable bare-die package 200, as shown in FIG. 4. Preferably, the encapsulant 240 has an exposed surface 241 coplanar to the bottom surface 212. When stacking a plurality of stackable bare-die packages 200, the exposed back surface 223 of the chip 220 of a lower stackable bare-die package 200 will not be touched nor stressed during stacking to eliminate die cracks of the chip 220.

The stackable bare-die package 200 further includes a plurality of external terminals 250 bonded onto the outer ball pads 215. As shown in FIG. 4, the stackable bare-die package 200 can electrically connect to an external printed circuit board 20 through the external terminals 250 or stack to another stackable bare-die package 200 by electrical connections between the external terminals 250 and the transfer pads 216 of another stackable bare-die package 200. In the present embodiment, the external terminals 250 are solder balls. But in different embodiments, the external terminals 250 can be metal plugs, solder bumps with solder paste, or metal needles. Preferably, the height of the external terminals 250 is slightly greater than the thickness of the chip 220 to avoid the exposed surface 241 of the encapsulant 240 to touch and stress on the exposed back surface 223 of the chip 220 or/and to avoid breaks of the external terminals 250.

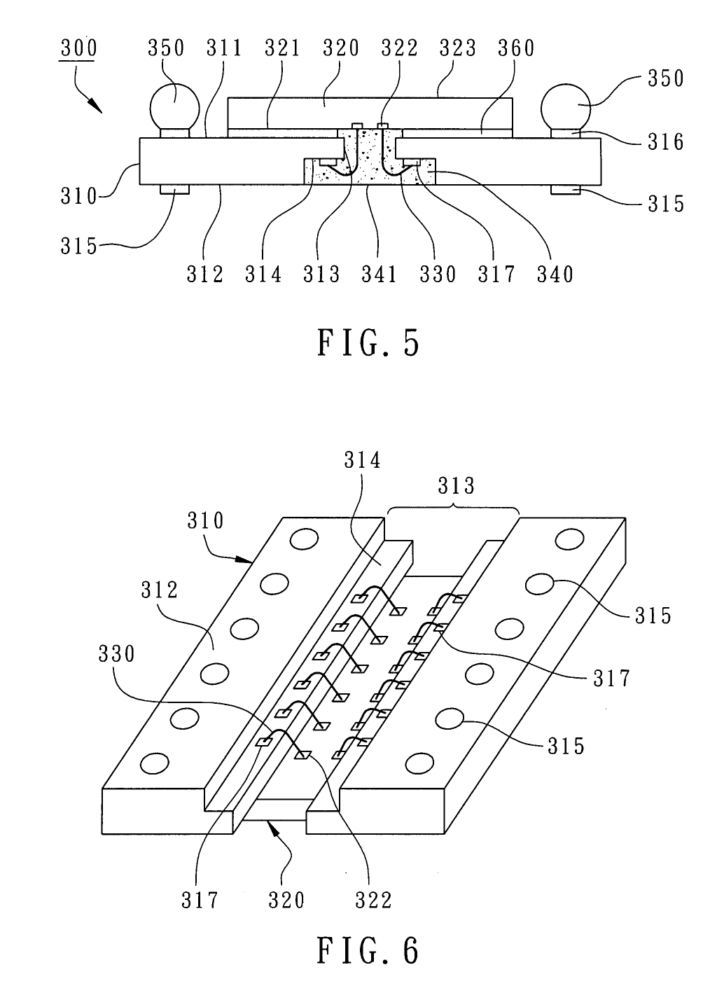

According to the second embodiment of the present invention, another stackable bare-die package is revealed in FIG. 5 where the stackable bare-die package 300 primarily comprises a substrate 310, a chip 320, a plurality of bonding wires 330 and an encapsulant 340.

As shown in FIG. 5 and FIG. 6, the substrate 310 has a top surface 311, a bottom surface 312 and a slot 313 where a step 314 is formed inside the slot 313. The substrate 310 further has a plurality of outer pads 315 formed on the bottom surface 312, a plurality of transfer pads 316 on the top surface 311 and a plurality of inner fingers 317 on the step 314. In the present embodiment, the slot 313 extends through the substrate 310 so that the substrate 310 is divided into two smaller sub-substrates, as shown in FIG. 6.

A plurality of bonding pads 322 are disposed on the active surface 321 of the chip 320. The active surface 321 of the chip 320 is attached to the top surface 311 of the substrate 320 by a die-attaching layer 360 with the bonding pads 322 aligned in the slot 313. The bonding pads 322 of the chip 320 are electrically connected to the inner fingers 317 by a plurality of bonding wires 330 passing through the slot 313.

An encapsulant 340 is formed inside the slot 313 to completely encapsulate the bonding wires 330. As shown in FIG. 5 and FIG. 6 again, the chip 320 has an exposed back surface 323. There is a height difference between the step 314 and the bottom surface 312 so that the loop heights of the bonding wires 330 don't exceed the bottom surface 312. Preferably, the encapsulant 340 has an exposed surface 341 in the same plane as the bottom surface 312 to avoid touching and stressing the exposed back surface 323 of the chip 320 to eliminate die cracks of the chip 320.

In the present embodiment, the stackable bare-die package 300 further has a plurality of external terminals 350 which are bonded onto the transfer pads 316 to protect the exposed back surface 323 of the chip 320 to avoid die cracks or scratches of the chip 320 during POP stacking or handling. The external terminals 350 can include solder balls. Preferably, the external terminals 350 are slightly higher than the exposed back surface 323 of the chip 320 to avoid the bottom surface 312 of the substrate 310 and the exposed surface 341 of the encapsulant 340 to touch and stress the exposed back surface 323 of the chip 320 during stacking another stackable bare-die package 300. Accordingly, a high density POP (Package-On-Package) stacking is possible.

The above description of embodiments of this invention is intended to be illustrative and not limiting. Other embodiments of this invention will be obvious to those skilled in the art in view of the above disclosure.

What is claimed is:

1. A stackable bare-die package comprises:
a substrate having a top surface, a bottom surface, a slot through the top and bottom surfaces and a step formed inside the slot, wherein the substrate further has a plurality of outer pads disposed on the bottom surface, a plurality of transfer pads on the top surface and a plurality of inner fingers on the step;
a chip disposed on the top surface of the substrate with a plurality of bonding pads aligned in the slot;
a plurality of bonding wires disposed in the slot and electrically connecting the bonding pads to the inner fingers; and
an encapsulant formed in the slot to completely encapsulate the bonding wires;
wherein the chip has an exposed back surface exposed from the encapsulant, and there is a height difference between the step and the bottom surface in a manner that the loop heights of the bonding wires don't exceed the bottom surface.

2. The stackable bare-die package of claim 1, wherein the encapsulant has an exposed surface coplanar to the bottom surface.

3. The stackable bare-die package of claim 1, further comprising a plurality of first external terminals bonded onto the outer pads.

4. The stackable bare-die package of claim 3, wherein the first external terminals include a plurality of solder balls.

5. The stackable bare-die package of claim 3, wherein the height of the first external terminals is slightly greater than the thickness of the chip.

6. The stackable bare-die package of claim 1, further comprising a plurality of second external terminals bonded onto to the transfer pads.

7. The stackable bare-die package of claim 6, wherein the second external terminals include a plurality of solder balls.

8. The stackable bare-die package of claim 6, wherein the second external terminals are slightly higher than the exposed back surface of the chip.

9. The stackable bare-die package of claim 1, wherein the height difference between the step and the bottom surface is not smaller than 70 μm.

10. The stackable bare-die package of claim 1, wherein the chip is a memory chip.

11. The stackable bare-die package of claim 1, wherein the slot extends through the substrate so that the substrate is divided into two smaller sub-substrates.
